(19) United States
(12) Patent Application Publication
(10) Pub. No.: US 2026/0213287 A1
(43) Pub. Date: Jul. 23, 2026

(54) CAPSULE-SENSOR SYSTEMS AND METHODS FOR BATTERY AGING AND THERMAL RUNAWAY DETECTION

(71) Applicants: Hyundai Motor Company, Seoul (KR); Kia Corporation, Seoul (KR)

(72) Inventors: Jung Kim, Superior Township, MI (US); Kyoung Pyo Ha, Superior Township, MI (US)

(21) Appl. No.: 19/033,194

(22) Filed: Jan. 21, 2025

(51) Int. Cl. H01M 10/42; G08B 21/18; H01M 50/342; H01M 50/375

(52) U.S. Cl. CPC H01M 10/4257; G08B 21/185; H01M 10/4285; H01M 50/3425; H01M 50/375; H01M 2200/10

(57) ABSTRACT

A battery health and safety management system and methods of use are provided. The battery health and safety management system may comprise a vehicle and an active sensing and venting module (ASVM) coupled to the vehicle, comprising a fan, one or more sensors, and a venting mechanism. The battery health and safety management system may comprise a battery pack comprising a plurality of battery cells, an insulator positioned between the plurality of battery cells, and one or more capsules positioned within or on the insulator. The one or more capsules may be configured to house a gas and rupture in the event of a battery pack anomaly, releasing the gas. The one or more sensors may be configured to detect the gas after a rupture of one or more of the one or more capsules.

### BACKGROUND

### Technical Field

Embodiments of the present disclosure relate to capsule-sensor systems and methods for battery aging and thermal runaway detection.

### Background

The thrust and other systems of electric vehicles (EVs) run on battery power. Because of this, battery anomalies can significantly affect the performance of an EV. Sensing battery anomalies in an early stage is critically important for several reasons.

For example, unmitigated EV operation on a battery pack with an abnormal cell will accelerate its aging. Additionally, the use of severely aged battery cell will eventually result in a thermal event, causing significant damage to the vehicle and risk to the passengers. Furthermore, sensing a problem with a battery early on will allow for an opportunity to service the EV in time to restore its optimal performance (e.g., improved range and performance), prevent costly repairs, and ensure safe operations.

There are some challenges to sensing battery anomalies at an early stage. For example, current EVs commonly rely on battery cell voltage and surface temperature sensors, which, due to sensitivity and other factors, may not be suitable to provide an accurate depiction of the pack status of a battery pack. Additionally, many alternative methods require state-of-the-art materials or technologies that are costly and difficult to implement. Furthermore, compatibility may be an issue since existing battery pack designs are highly optimized for specific energy and energy density, and improving pack safety without compromising the performance is a difficult task.

A battery pack state of health (SOH) may be predicted by the uniformity of battery cell voltage measurements. However, battery cell voltage measurements often do not correlate with SOH in a predictable manner. Many EVs perform cell voltage balancing periodically to optimize its performance. As a result, vehicle-reported SOH values are frequently questioned.

For at least these reasons, systems and methos are needed for detecting severe battery aging and thermal runaway in early stages in a cost effective and efficient manner.

### SUMMARY

According to an object of the present disclosure, a battery health and safety management system is provided. The battery health and safety management system may comprise a vehicle and an active sensing and venting module (ASVM) coupled to the vehicle, comprising a fan, one or more sensors, and a venting mechanism. The battery health and safety management system may comprise a battery pack comprising a plurality of battery cells, an insulator positioned between the plurality of battery cells, and one or more capsules positioned within or on the insulator. The one or more capsules may be configured to house a gas and rupture in the event of a battery pack anomaly (e.g. as a consequence of a thermal event in a battery cell), releasing the gas. The one or more sensors may be configured to detect the gas after a rupture of one or more of the one or more capsules.

According to an exemplary embodiment, the battery health and safety management system may comprise a computing device comprising a processor and a memory, coupled to the ASVM.

According to an exemplary embodiment, the memory may be configured to store instructions that, when executed by the processor, are configured to cause the processor to record sensor data via the one or more sensors and determine whether the sensor data is within an expected range.

According to an exemplary embodiment, the instructions, when executed by the processor, may be configured to cause the processor to, when the sensor data is within the expected range, generate a vehicle-specific correlation between controller area network (CAN) data and the sensor data and update the expected range.

According to an exemplary embodiment, the instructions, when executed by the processor, may be configured to cause the processor to, when the sensor data is not within the expected range, activate an alert status comprising implementing alert logic.

According to an exemplary embodiment, the implementing the alert logic may comprise determining whether the sensor date rose above or dropped below the expected range.

According to an exemplary embodiment, the implementing the alert logic may comprise, when the sensor data dropped below the expected range, determining that the battery pack comprises a compromised seal and generating an alert to one or more passengers of the vehicle to exit the vehicle.

According to an exemplary embodiment, the one or more sensors may comprise a CO concentration sensor; a CO₂ concentration sensor, and an airflow thermometer. According to an exemplary embodiment, the implementing the alert logic may comprise, when the sensor data rose above the expected range, determining whether elevated levels in the sensor data are observed in gas concentrations, released from the capsules, and in an internal air temperature.

According to an exemplary embodiment, the implementing the alert logic may comprise, when the elevated levels in the sensor data are not observed in the gas concentrations and in the internal air temperature, determining that the battery pack is experiencing severe aging and limiting battery current of the battery pack.

According to an exemplary embodiment, the implementing the alert logic may comprise, when the elevated levels in the sensor data are observed in the gas concentrations and in the internal air temperature, limiting battery output of the battery pack.

According to an exemplary embodiment, the implementing the alert logic may comprise, after limiting the battery output of the battery pack, determining whether the sensor data continues to increase and, when the sensor data continues to increase, opening the venting mechanism to allow venting.

According to an object of the present disclosure, a method for detecting battery anomalies of a vehicle is provided. The method may comprise recording sensor data via one or more sensors of a battery health and safety management system. The battery health and safety management system may comprise the vehicle and an ASVM coupled to the vehicle, comprising a fan, the one or more sensors, and a venting mechanism. The battery health and safety management system may comprise a battery pack comprising a plurality of battery cells, an insulator positioned between the plurality of battery cells, and one or more capsules preferably positioned proximate to the insulator, such as within or on the insulator. The one or more capsules may be configured to house a gas and rupture in the event of a battery pack anomaly (e.g. as a consequence of a thermal event in a battery cell), releasing the gas. The one or more sensors may be configured to detect the gas after a rupture of one or more of the one or more capsules. The method may comprise determining, using a computing device comprises a processor and a memory, whether the sensor data is within an expected range. The one or more capsules can be a variety of shapes and configurations and comprise a range of materials of construction that can house and release the gas.

According to an exemplary embodiment, the method may comprise, using the computing device, generating a vehicle-specific correlation between CAN data and the sensor data and updating the expected range.

According to an exemplary embodiment, the method may comprise, when the sensor data is not within the expected range, activating an alert status comprising implementing alert logic.

According to an exemplary embodiment, the implementing the alert logic may comprise determining whether the sensor date rose above or dropped below the expected range.

According to an exemplary embodiment, the implementing the alert logic may comprise, when the sensor data dropped below the expected range, determining that the battery pack comprises a compromised seal and generating an alert to one or more passengers of the vehicle to exit the vehicle.

According to an exemplary embodiment, the one or more sensors may comprise a CO concentration sensor, a CO₂ concentration sensor, and an airflow thermometer. According to an exemplary embodiment, the implementing the alert logic comprises, when the sensor data rose above the expected range, determining whether elevated levels in the sensor data are observed in gas concentrations, released from the capsules, and in an internal air temperature.

According to an exemplary embodiment, the implementing the alert logic may comprise, when the elevated levels in the sensor data are not observed in the gas concentrations and in the internal air temperature, determining that the battery pack is experiencing severe aging and limiting battery current of the battery pack.

According to an exemplary embodiment, the implementing the alert logic may comprise, when the elevated levels in the sensor data are observed in the gas concentrations and in the internal air temperature, limiting battery output of the battery pack.

According to an exemplary embodiment, the implementing the alert logic may comprise, after limiting the battery output of the battery pack, determining whether the sensor data continues to increase and, when the sensor data continues to increase, opening the venting mechanism to allow venting.

### BRIEF DESCRIPTION OF THE DRAWINGS

The accompanying drawings, which are incorporated in and form a part of the Detailed Description, illustrate various non-limiting and non-exhaustive embodiments of the subject matter and, together with the Detailed Description, serve to explain principles of the subject matter discussed below. Unless specifically noted, the drawings referred to in this Brief Description of Drawings should be understood as not being drawn to scale and like reference numerals refer to like parts throughout the various figures unless otherwise specified.

FIG. 1 illustrates an exploded view of thermal and mechanical insulators placed between battery cells, according to an exemplary embodiment of the present disclosure.

FIG. 2 illustrates example capsules containing signal gas species, according to an exemplary embodiment of the present disclosure.

FIG. 3 illustrates capsules inserted between battery cells of a battery health and safety management system, according to an exemplary embodiment of the present disclosure.

FIG. 4 illustrates an active sensing and venting module (ASVM) of a battery health and safety management system, according to an exemplary embodiment of the present disclosure.

FIG. 5 illustrates an ASVM positioned within a vehicle, according to an exemplary embodiment of the present disclosure.

FIGS. 6A-6B illustrate a flowchart of a method for detecting battery aging and thermal runaway, according to an exemplary embodiment of the present disclosure.

FIG. 7 illustrates an example architecture of a vehicle, according to an exemplary embodiment of the present disclosure.

FIG. 8 illustrates example elements of a computing device, according to an exemplary embodiment of the present disclosure.

### DETAILED DESCRIPTION

The following Detailed Description is merely provided by way of example and not of limitation. Furthermore, there is no intention to be bound by any expressed or implied theory presented in the preceding background or in the following Detailed Description.

Reference will now be made in detail to various exemplary embodiments of the subject matter, examples of which are illustrated in the accompanying drawings. While various embodiments are discussed herein, it will be understood that they are not intended to limit to these embodiments. On the contrary, the presented embodiments are intended to cover alternatives, modifications, and equivalents, which may be included within the spirit and scope of the various embodiments as defined by the appended claims. Furthermore, in this Detailed Description, numerous specific details are set forth in order to provide a thorough understanding of embodiments of the present subject matter. However, embodiments may be practiced without these specific details. In other instances, well known methods, procedures, components, and circuits have not been described in detail as not to unnecessarily obscure aspects of the described embodiments.

Some portions of the detailed descriptions which follow are presented in terms of procedures, logic blocks, processing, and other symbolic representations of operations on data within an electrical device. These descriptions and representations are the means used by those skilled in the data processing arts to most effectively convey the substance of their work to others skilled in the art. In the present application, a procedure, logic block, process, or the like, is conceived to be one or more self-consistent procedures or instructions leading to a desired result. The procedures are those requiring physical manipulations of physical quantities. Usually, although not necessarily, these quantities may take the form of electrical or magnetic signals capable of being stored, transferred, combined, compared, and otherwise manipulated in an electronic system, device, and/or component.

It should be borne in mind, however, that these and similar terms are to be associated with the appropriate physical quantities and are merely convenient labels applied to these quantities. Unless specifically stated otherwise as apparent from the following discussions, it is appreciated that throughout the description of embodiments, discussions utilizing terms such as “determining,” “communicating,” “taking,” “comparing,” “monitoring,” “calibrating,” “estimating,” “initiating,” “providing,” “receiving,” “controlling,” “transmitting,” “isolating,” “generating,” “aligning,” “synchronizing,” “identifying,” “maintaining,” “displaying,” “switching,” or the like, refer to the actions and processes of an electronic item such as: a processor, a sensor processing unit (SPU), a processor of a sensor processing unit, an application processor of an electronic device/system, or the like, or a combination thereof. The item manipulates and transforms data represented as physical (electronic and/or magnetic) quantities within the registers and memories into other data similarly represented as physical quantities within memories or registers or other such information storage, transmission, processing, or display components.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles. In aspects, a vehicle may comprise an internal combustion engine system as disclosed herein.

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. These terms are merely intended to distinguish one component from another component, and the terms do not limit the nature, sequence or order of the constituent components. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof.

Although exemplary embodiment is described as using a plurality of units to perform the exemplary process, it is understood that the exemplary processes may also be performed by one or plurality of modules. Additionally, it is understood that the term controller/control unit refers to a hardware device that includes a memory and a processor and is specifically programmed to execute the processes described herein. The memory is configured to store the modules and the processor is specifically configured to execute said modules to perform one or more processes which are described further below.

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

Embodiments described herein may be discussed in the general context of processor-executable instructions residing on some form of non-transitory processor-readable medium, such as program modules, executed by one or more computers or other devices. Generally, program modules include routines, programs, objects, components, data structures, etc., that perform particular tasks or implement particular abstract data types. The functionality of the program modules may be combined or distributed as desired in various embodiments.

In the figures, a single block may be described as performing a function or functions; however, in actual practice, the function or functions performed by that block may be performed in a single component or across multiple components, and/or may be performed using hardware, using software, or using a combination of hardware and software. To clearly illustrate this interchangeability of hardware and software, various illustrative components, blocks, modules, logic, circuits, and steps have been described generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Also, the example device vibration sensing system and/or electronic device described herein may include components other than those shown, including well-known components.

Various techniques described herein may be implemented in hardware, software, firmware, or any combination thereof, unless specifically described as being implemented in a specific manner. Any features described as modules or components may also be implemented together in an integrated logic device or separately as discrete but interoperable logic devices. If implemented in software, the techniques may be realized at least in part by a non-transitory processor-readable storage medium comprising instructions that, when executed, perform one or more of the methods described herein. The non-transitory processor-readable data storage medium may form part of a computer program product, which may include packaging materials.

The non-transitory processor-readable storage medium may comprise random access memory (RAM) such as synchronous dynamic random access memory (SDRAM), read only memory (ROM), non-volatile random access memory (NVRAM), electrically erasable programmable read-only memory (EEPROM), FLASH memory, other known storage media, and the like. The techniques additionally, or alternatively, may be realized at least in part by a processor-readable communication medium that carries or communicates code in the form of instructions or data structures and that can be accessed, read, and/or executed by a computer or other processor.

Various embodiments described herein may be executed by one or more processors, such as one or more motion processing units (MPUs), sensor processing units (SPUs), host processor(s) or core(s) thereof, digital signal processors (DSPs), general purpose microprocessors, application specific integrated circuits (ASICs), application specific instruction set processors (ASIPs), field programmable gate arrays (FPGAs), a programmable logic controller (PLC), a complex programmable logic device (CPLD), a discrete gate or transistor logic, discrete hardware components, or any combination thereof designed to perform the functions described herein, or other equivalent integrated or discrete logic circuitry. The term “processor,” as used herein may refer to any of the foregoing structures or any other structure suitable for implementation of the techniques described herein. As employed in the subject specification, the term “processor” can refer to substantially any computing processing unit or device comprising, but not limited to comprising, single-core processors; single-processors with software multithread execution capability; multi-core processors; multi-core processors with software multithread execution capability; multi-core processors with hardware multithread technology; parallel platforms; and parallel platforms with distributed shared memory. Moreover, processors can exploit nano-scale architectures such as, but not limited to, molecular and quantum-dot based transistors, switches and gates, in order to optimize space usage or enhance performance of user equipment. A processor may also be implemented as a combination of computing processing units.

In addition, in some aspects, the functionality described herein may be provided within dedicated software modules or hardware modules configured as described herein. Also, the techniques could be fully implemented in one or more circuits or logic elements. A general purpose processor may be a microprocessor, but in the alternative, the processor may be any processor, controller, microcontroller, or state machine. A processor may also be implemented as a combination of computing devices, e.g., a combination of an SPU/MPU and a microprocessor, a plurality of microprocessors, one or more microprocessors in conjunction with an SPU core, MPU core, or any other such configuration. One or more components of an SPU or electronic device described herein may be embodied in the form of one or more of a “chip,” a “package,” an Integrated Circuit (IC).

According to exemplary embodiments, capsule-sensor systems and methods for battery aging and thermal runaway detection are provided.

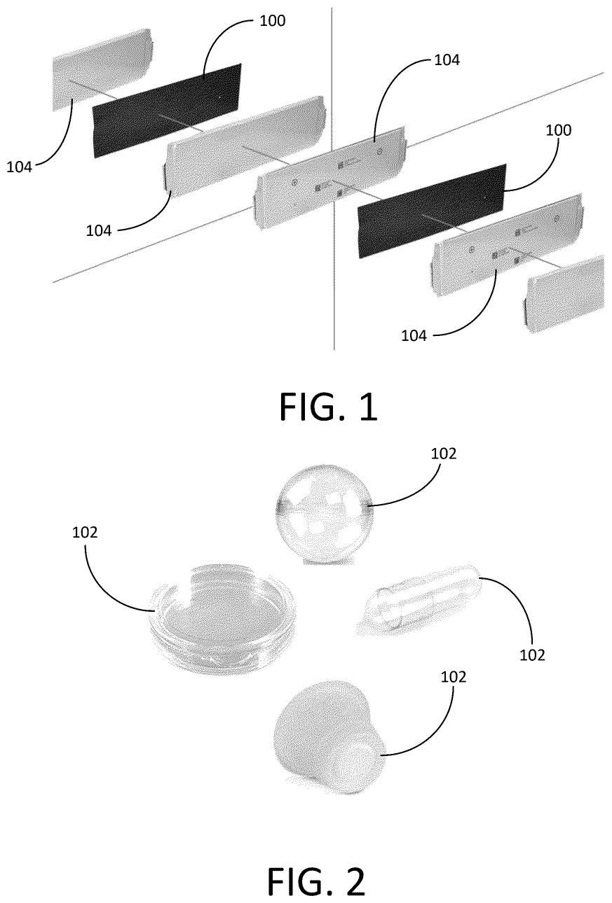

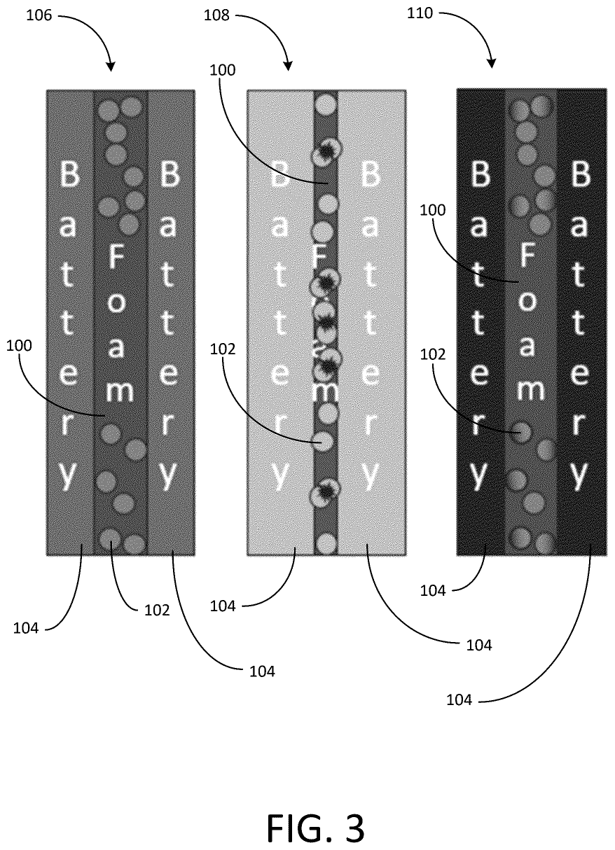

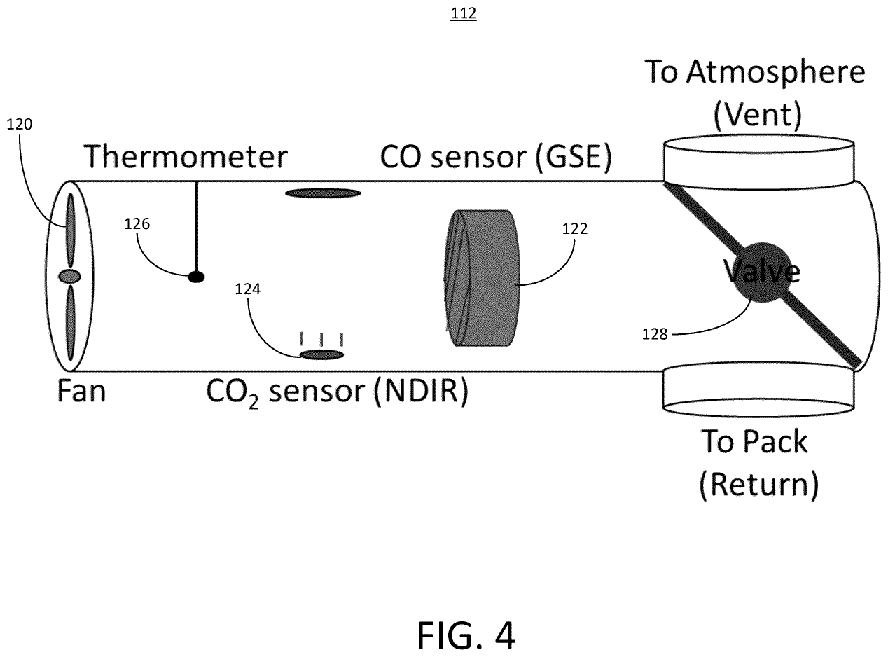

Referring now to FIGS. 1-3, an exploded view of thermal and mechanical insulators 100 placed between battery cells 104 (FIG. 1), capsules 102 containing signal gas species, and capsules 102 inserted between battery cells 104 (FIG. 3) of a battery health and safety management system are illustratively depicted, in accordance with an exemplary embodiment of the present disclosure.

Thermal and mechanical insulators 100 are commonly placed between battery cells in modern electric vehicles (EVs). According to an exemplary embodiment, the capsules 102 may be embedded in the thermal and mechanical insulators 100. The thermal and mechanical insulators 100 may be positioned between the battery cells 104 in the battery health and safety management system. According to an exemplary embodiment, the thermal and mechanical insulators 100 may comprise foam. It is noted, however, that the thermal and mechanical insulators 100 may comprise one or more other suitable materials while maintaining the spirit and functionality of the present disclosure.

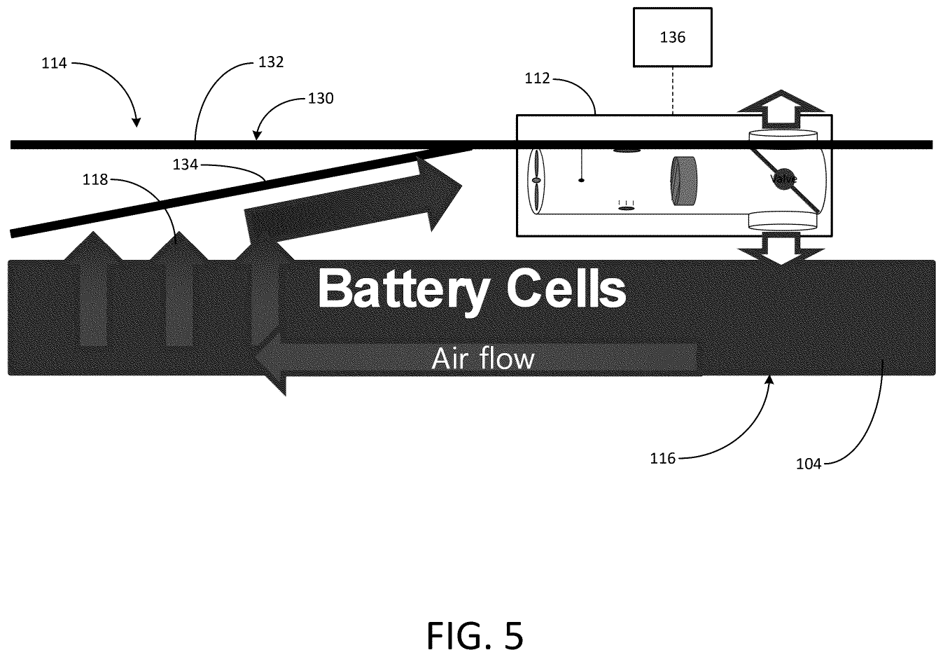

According to an exemplary embodiment, the choice of gas in the capsules 102 may be adjusted based on the chemistry of battery cells 104. For various Li-ion cells, CO and CO₂ gases may be incorporated as paired sensors (as shown, e.g., in FIG. 4) may be configured to detect other phenomena (e.g., venting). According to an exemplary embodiment, the inserted capsules 102 applied between battery cells 104 may be configured to open and release the contained gas species when high temperature or pressure is applied by abnormally behaving battery cells. For example, as shown in FIG. 3, battery cells 104 under regular operation (scenario 106), under swollen operation wherein one or more of the battery cells 104 are swollen (scenario 108, indicating mechanical rupture), and under thermal runaway onset operation (scenario 110, indicating thermal melt) are illustrated. It is noted, however, that other battery anomaly situations may occur causing the capsules 102 to rupture.

According to an exemplary embodiment, the capsules 102 may comprise plastic (e.g., ABS, PBT, HDPE, etc.). It is noted, however, that the capsules 102 may comprise one or more other suitable materials. The capsules 102 may be configured to have varying ranges of melting points, rupture pressure, and/or other physical properties to enable the battery health and safety management system to work without being tied to specific physical or chemical types of batteries.

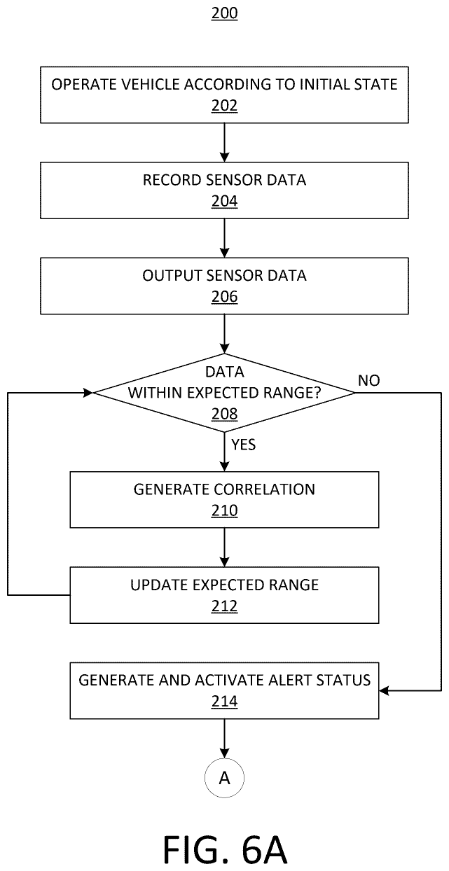

Referring now to FIGS. 4-5, an active sensing and venting module (ASVM) 112 (FIG. 4) of a battery health and safety management system, and an ASVM 112 positioned within a vehicle 114 (FIG. 5) are illustratively depicted, in accordance with an exemplary embodiment of the present disclosure.

According to an exemplary embodiment, the ASVM 112 may be placed at a strategic location within or on the vehicle 114 to monitor the thermal and chemical status within the battery pack 116. The battery pack may comprise one or more battery cells 104. According to an exemplary embodiment, the ASVM 112 may be placed in a top region of the battery pack 116. Being placed in the top region of the battery pack 116 will effectively enable the ASVM 112 to collect, monitor, and vent rising gases 118 heated by the battery cells 104 of the battery pack 116.

According to an exemplary embodiment, the ASVM 112 may comprise a fan 120, a series of sensors (e.g., a CO concentration sensor 122, a CO₂ concentration sensor 124, an airflow thermometer 126, and/or other suitable sensor), a venting mechanism 128, and/or other suitable components. According to an exemplary embodiment, the fan 120 may be configured to aid in natural convection to generate a moderate and constant air flow for responsive and accurate monitoring.

According to an exemplary embodiment, the CO concentration sensor 122 may comprise a gas sensitive electrochemical (GSE) sensor or other suitable sensor. The CO concentration sensor 122 may be configured to have a range of 0 to 50 ppm and a resolution of 0.1 ppm. It is noted, however, that the CO concentration sensor 122 may be configured to have other ranges and/or resolutions, while maintaining the spirit and functionality of the present disclosure.

According to an exemplary embodiment, the CO₂ concentration sensor 124 may comprise a non-dispersive infrared (NDIR) sensor or other suitable sensor. The CO₂ concentration sensor 124 may be configured to have a range of 0 to 5000 ppm and a resolution of 1 ppm. It is noted, however, that the CO₂ concentration sensor 124 may be configured to have other ranges and/or resolutions, while maintaining the spirit and functionality of the present disclosure.

According to an exemplary embodiment, the vehicle 114 may comprise a battery pack 116 enclosure 130. The battery pack 116 enclosure 130 may comprise a top cover 132. According to an exemplary embodiment, the battery pack 116 enclosure 130 may comprise a guide structure 134 added to the top cover 132 to guide the gases 118 and enhance the effectiveness of the battery health and safety management system.

According to an exemplary embodiment, the ASVM 112 may comprise and/or be coupled to a computing device 136. The computing device 136 may be configured to perform one or more functions of the ASVM 112, the vehicle 114, and/or other suitable components.

According to an exemplary embodiment, the battery health and safety management system may comprise the ASVM 112, the battery pack 116, the vehicle 114, the computing device 136, the capsules 102, and/or other suitable components.

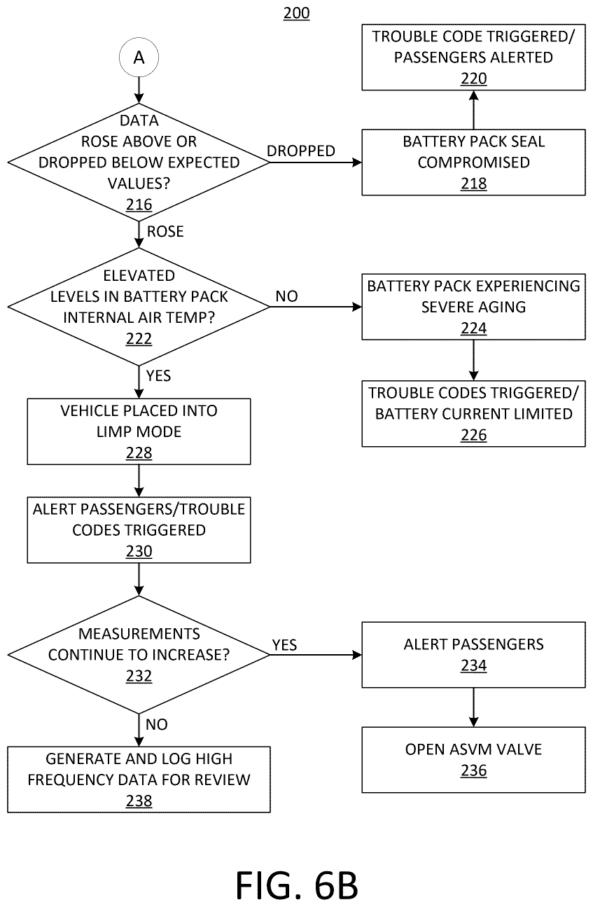

Referring now to FIGS. 6A-6B, a flowchart of a method 200 for detecting battery aging and thermal runaway is illustratively depicted, in accordance with an exemplary embodiment of the present disclosure.

According to an exemplary embodiment, at 202, the vehicle may operate according to an initial state (new vehicle or system reset). In the initial state, the vehicle may operate on a default map which provides an expected range of parameters. For example, a factory tune offers a range of parameters wide enough to allow the vehicle to operate in various climates and operation scenarios unless an obvious problem is detected.

At 204, the one or more sensors of the ASVM may record data (e.g., sensor readings) and, at 206, the ASVM may output the data. According to an exemplary embodiment, the data may comprise responsive time data vs. temperature data and gas species concentration (e.g., CO & CO₂) data during various charging and discharging scenarios.

At 208, the ASVM sensor outputs (the data) may be compared to the expected values to determine whether the data is within an expected range.

When the data is within an expected range, then, at 210, the data may be utilized to generate a vehicle-specific correlation between controller area network (CAN) and ASVM readings. In order to generate the vehicle-specific correlation, the ASVM readings (the data) may be logged and correlated to vehicle operations. According to an exemplary embodiment, the vehicle operations may be based on the CAN data. The CAN data may comprise battery current data, voltage data, battery surface temperature data, ambient air temperature data, etc., to represent a vehicle operation scenario. According to an exemplary embodiment, the ASVM recordings in each vehicle operations scenario may be used to generate statistics to correlate the data to the CAN readings.

Over time, accumulated data may yield expected ranges of ASVM values in various operation scenarios, such as, e.g., spirited driving in a high temperature environment, fast-charging in a cold temperature environment, etc. At 212, the expected range may be updated. The updated expected range may be vehicle-specific based on the ASVM data and the various operation scenarios. Once the expected range is updated, then, at 208, the ASVM sensor outputs (the data) may be compared to the expected values to determine whether the data is within an expected range.

When the data is not within an expected range, then, at 214, an alert status may be generated and activated from the ASVM. According to an exemplary embodiment, the activating the alert status may comprise implementing and activating alert logic to take appropriate actions when ASVM readings deviate from expected values.

At 216, it may be determined whether the ASVM sensor data is lower or higher than the expected range of values.

When the ASVM sensor data dropped below the expected values, then, at 218, it may be determined that a battery pack seal has been compromised. A sudden drop in sensor measurements (e.g., air temperature, CO and CO₂ concentrations) may indicate a compromised seal of the battery pack. To prevent further damage (e.g. water ingress), the ASVM, at 220, may trigger a trouble code and alert passengers to have the battery pack serviced.

When the ASVM sensor data rose above the expected values, then, at 222, it may be determined whether the elevated levels were observed in gas concentrations (e.g., CO, CO₂) only, or in the battery pack internal air temperature as well.

When the elevated levels are not observed in the battery pack internal air temperature, then, at 224, it may be determined that the battery pack is experiencing severe aging. Elevated gas concentration, resulting from the gas released that was embedded in the capsules, without a significant battery pack internal air temperature increase indicates severe aging (e.g., battery cell swelling and/or abnormal heat generation). To help prevent further damage, at 226, battery current may be limited at half the maximum values in charging and driving scenarios and trouble codes may be triggered to alert passengers and aid technicians in servicing the vehicle.

An increase in all measurements may indicate a first venting event which may occur before a thermal runaway event occurs and/or that there is an imminent thermal runaway. Because of this, when the elevated levels are observed in the battery pack internal air temperature, then, at 228, the vehicle may be immediately put into a limp mode, wherein the battery output is severely limited. Passengers may then be alerted, at 230, to park and exit the vehicle as safely as possible, trouble codes may be triggered, and key measurements may be logged for review. CO, CO₂, and/or other suitable measurements may be used to predict thermal runaway.

At 232, it may be determined whether the ASVM measurements (the data) continue to increase, despite the vehicle being put into the limp mode. When the ASVM measurements keep increasing despite the vehicle being put in limp mode, then, at 234, passengers may be alerted to exit the vehicle as soon as possible and, at 236, the ASVM module valve of the venting mechanism may be opened to atmosphere to allow venting. When the ASVM measurements stabilize, then, at 238, the (8) the battery health and safety management system may remain on alert, generating and logging high frequency data for review.

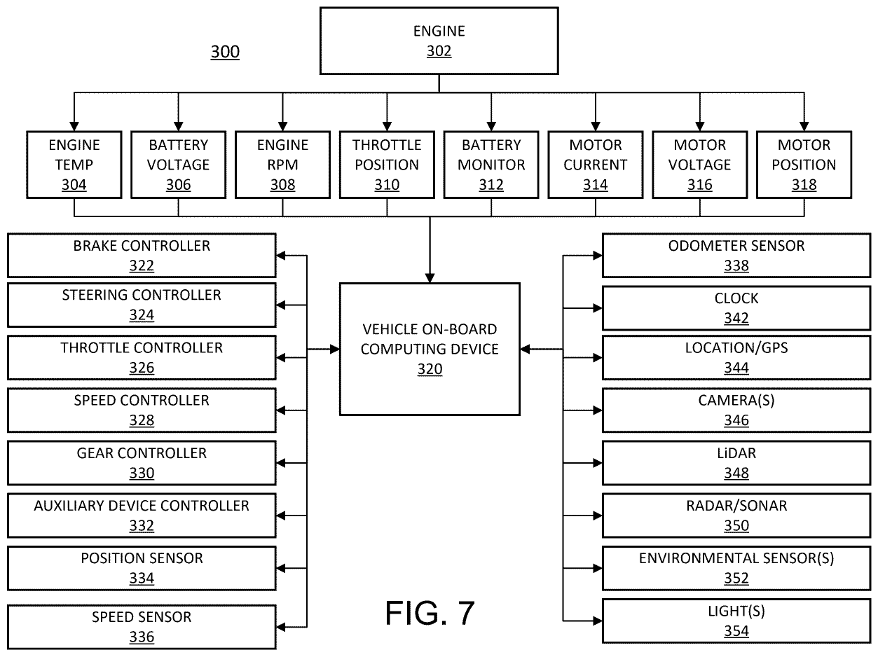

Referring now to FIG. 7, an example vehicle system architecture 300 for a vehicle is provided, in accordance with an exemplary embodiment of the present disclosure. The following discussion of vehicle system architecture 300 is sufficient for understanding one or more components of vehicle 114.

As shown in FIG. 6, the vehicle system architecture 300 may comprise an engine, motor or propulsive device 302 and various sensors 304-318 for measuring various parameters of the vehicle system architecture 300, such as, but not limited to, those of the vehicle snapshot described above. In gas-powered or hybrid vehicles having a fuel-powered engine, the sensors 304-318 may comprise, for example, an engine temperature sensor 304, a battery voltage sensor 306, an engine Rotations Per Minute (RPM) sensor 308, and/or a throttle position sensor 310. If the vehicle is an electric or hybrid vehicle, then the vehicle may comprise an electric motor, and accordingly may comprise sensors such as a battery monitoring system 312 (to measure current, voltage and/or temperature of the battery), motor current 314 and voltage 316 sensors, and motor position sensors such as resolvers and encoders 318.

Operational parameter sensors that are common to both types of vehicles may comprise, for example: a position sensor 334 such as an accelerometer, gyroscope and/or inertial measurement unit; a speed sensor 336; and/or an odometer sensor 338. The vehicle system architecture 300 also may comprise a clock 342 that the system uses to determine vehicle time and/or date during operation. The clock 342 may be encoded into the vehicle on-board computing device 320, it may be a separate device, or multiple clocks may be available.

The vehicle system architecture 300 may comprise various sensors that operate to gather information about the environment in which the vehicle is traveling. These sensors may comprise, for example: a location sensor 344 (for example, a Global Positioning System (GPS) device); object detection sensors such as one or more cameras 346; a LiDAR sensor system 348; and/or a radar and/or a sonar system 350. The sensors may comprise environmental sensors 352 such as, e.g., a humidity sensor, a precipitation sensor, a light sensor, and/or ambient temperature sensor. The object detection sensors may be configured to enable the vehicle system architecture 300 to detect objects that are within a given distance range of the vehicle in any direction, while the environmental sensors 352 may be configured to collect data about environmental conditions within the vehicle's area of travel. According to an exemplary embodiment, the vehicle system architecture 300 may comprise one or more lights 354 (e.g., headlights, flood lights, flashlights, etc.).

During operations, information may be communicated from the sensors to an on-board computing device 320 (e.g., computing device 136 and computing device 400). The on-board computing device 320 may be configured to analyze the data captured by the sensors and/or data received from data providers and may be configured to optionally control operations of the vehicle system architecture 300 based on results of the analysis. For example, the on-board computing device 320 may be configured to control: braking via a brake controller 322; direction via a steering controller 324; speed and acceleration via a throttle controller 326 (in a gas-powered vehicle) or a motor speed controller 328 (such as a current level controller in an electric vehicle); a differential gear controller 330 (in vehicles with transmissions); and/or other controllers. The brake controller 322 may comprise a pedal effort sensor, pedal effort sensor, and/or simulator temperature sensor, as described herein.

Geographic location information may be communicated from the location sensor 344 to the on-board computing device 320, which may then access a map of the environment that corresponds to the location information to determine known fixed features of the environment such as streets, buildings, stop signs and/or stop/go signals. Captured images from the cameras 346 and/or object detection information captured from sensors such as LiDAR 348 may be communicated from those sensors to the on-board computing device 320. The object detection information and/or captured images may be processed by the on-board computing device 320 to detect objects in proximity to the vehicle. Any known or to be known technique for making an object detection based on sensor data and/or captured images may be used in the embodiments disclosed in this document.

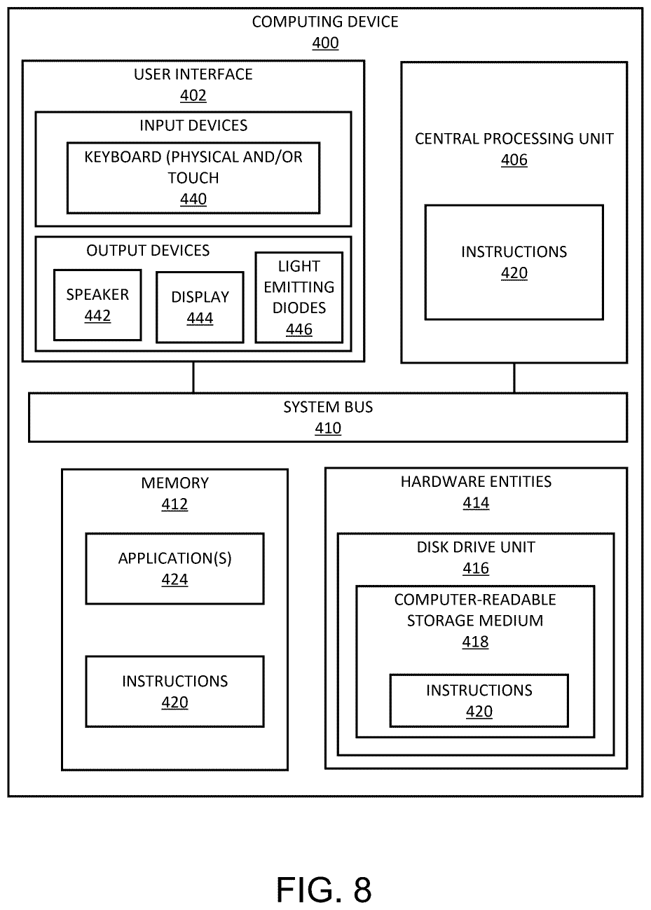

Referring now to FIG. 8, an illustration of an example architecture for a computing device 400 is provided. According to an exemplary embodiment, one or more functions of the present disclosure may be implemented by a computing device such as, e.g., computing device 400 or a computing device similar to computing device 400. Computing device 400 may be a quantum computer, a classical computer, and/or have one or more components configured to perform one or more quantum and/or classical computing functions. Computing device 136 and/or computing device 320 may be an example of computing device 400 and/or may comprise one or more components of computing device 400.

The hardware architecture of FIG. 8 represents one example implementation of a representative computing device configured to implement at least a portion of the systems/devices (e.g., vehicle 114 and ASVM 112) and method(s)/control logic(s) (e.g., method 200) described herein.

Some or all components of the computing device 400 may be implemented as hardware, software, and/or a combination of hardware and software. The hardware may comprise, but is not limited to, one or more electronic circuits. The electronic circuits may comprise, but are not limited to, passive components (e.g., resistors and capacitors) and/or active components (e.g., amplifiers and/or microprocessors). The passive and/or active components may be adapted to, arranged to, and/or programmed to perform one or more of the methodologies, procedures, or functions described herein.

As shown in FIG. 8, the computing device 400 may comprise a user interface 402 (e.g., a graphical user interface), a Central Processing Unit (“CPU”) 406, a system bus 410, a memory 412 connected to and accessible by other portions of computing device 400 through system bus 410, and hardware entities 414 connected to system bus 410. The user interface may comprise input devices and output devices, which may be configured to facilitate user-software interactions for controlling operations of the computing device 400. The input devices may comprise, but are not limited to, a physical and/or touch keyboard 440. The input devices may be connected to the computing device 400 via a wired or wireless connection (e.g., a Bluetooth® connection). The output devices may comprise, but are not limited to, a speaker 442, a display 444, and/or light emitting diodes 446.

At least some of the hardware entities 414 may be configured to perform actions involving access to and use of memory 412, which may be a Random Access Memory (RAM), a disk driver and/or a Compact Disc Read Only Memory (CD-ROM), among other suitable memory types. Hardware entities 414 may comprise a disk drive unit 416 comprising a computer-readable storage medium 418 on which may be stored one or more sets of instructions 420 (e.g., programming instructions such as, but not limited to, software code) configured to implement one or more of the methodologies, procedures, or functions described herein. The instructions 420 may also reside, completely or at least partially, within the memory 412 and/or within the CPU 406 during execution thereof by the computing device 400.

The memory 412 and the CPU 406 may also constitute machine-readable media. The term “machine-readable media”, as used here, refers to a single medium or multiple media (e.g., a centralized or distributed database, and/or associated caches and servers) that store the one or more sets of instructions 420. The term “machine-readable media”, as used here, also refers to any medium that is capable of storing, encoding, or carrying a set of instructions 420 for execution by the computing device 400 and that cause the computing device 400 to perform any one or more of the methodologies of the present disclosure. According to various embodiments, one or more computer applications 424 may be stored on the memory 412.

What has been described above includes examples of the subject disclosure. It is, of course, not possible to describe every conceivable combination of components or methodologies for purposes of describing the subject matter, but it is to be appreciated that many further combinations and permutations of the subject disclosure are possible. Accordingly, the claimed subject matter is intended to embrace all such alterations, modifications, and variations that fall within the spirit and scope of the appended claims.

In particular and in regard to the various functions performed by the above described components, devices, systems and the like, the terms (including a reference to a “means”) used to describe such components are intended to correspond, unless otherwise indicated, to any component which performs the specified function of the described component (e.g., a functional equivalent), even though not structurally equivalent to the disclosed structure, which performs the function in the herein illustrated exemplary aspects of the claimed subject matter.

The aforementioned systems and components have been described with respect to interaction between several components. It can be appreciated that such systems and components can include those components or specified sub-components, some of the specified components or sub-components, and/or additional components, and according to various permutations and combinations of the foregoing. Sub-components can also be implemented as components communicatively coupled to other components rather than included within parent components (hierarchical). Additionally, it should be noted that one or more components may be combined into a single component providing aggregate functionality or divided into several separate sub-components. Any components described herein may also interact with one or more other components not specifically described herein.

In addition, while a particular feature of the subject innovation may have been disclosed with respect to only one of several implementations, such feature may be combined with one or more other features of the other implementations as may be desired and advantageous for any given or particular application. Furthermore, to the extent that the terms “includes,” “including,” “has,” “contains,” variants thereof, and other similar words are used in either the detailed description or the claims, these terms are intended to be inclusive in a manner similar to the term “comprising” as an open transition word without precluding any additional or other elements.

Thus, the embodiments and examples set forth herein were presented in order to best explain various selected embodiments of the present invention and its particular application and to thereby enable those skilled in the art to make and use embodiments of the invention. However, those skilled in the art will recognize that the foregoing description and examples have been presented for the purposes of illustration and example only. The description as set forth is not intended to be exhaustive or to limit the embodiments of the invention to the precise form disclosed.

What is claimed is:

1. A battery health and safety management system, comprising:
a vehicle;
an active sensing and venting module (ASVM) coupled to the vehicle, comprising:
a fan;
one or more sensors; and
a venting mechanism; and
a battery pack comprising:
a plurality of battery cells;
an insulator positioned between the plurality of battery cells; and
one or more capsules positioned within or on the insulator,
wherein:
the one or more capsules are configured to:
house a gas; and
rupture in a thermal event in a battery cell, releasing the gas, and
the one or more sensors are configured to detect the gas after a rupture of one or more of the one or more capsules.

2. The battery health and safety management system of claim 1, further comprising a computing device comprising a processor and a memory, coupled to the ASVM.

3. The battery health and safety management system of claim 2, wherein the memory is configured to store instructions that, when executed by the processor, are configured to cause the processor to:
record sensor data via the one or more sensors; and
determine whether the sensor data is within an expected range.

4. The battery health and safety management system of claim 3, wherein the instructions, when executed by the processor, are configured to cause the processor to, when the sensor data is within the expected range:
generate a vehicle-specific correlation between controller area network (CAN) data and the sensor data; and
update the expected range.

5. The battery health and safety management system of claim 3, wherein the instructions, when executed by the processor, are configured to cause the processor to, when the sensor data is not within the expected range, activate an alert status comprising implementing alert logic.

6. The battery health and safety management system of claim 5, wherein the implementing the alert logic comprises determining whether the sensor date rose above or dropped below the expected range.

7. The battery health and safety management system of claim 6, wherein the implementing the alert logic comprises, when the sensor data dropped below the expected range:
determining that the battery pack comprises a compromised seal; and
generating an alert to one or more passengers of the vehicle to exit the vehicle.

8. The battery health and safety management system of claim 6, wherein:
the one or more sensors comprise a CO concentration sensor; a CO₂ concentration sensor; and an airflow thermometer, and
the implementing the alert logic comprises, when the sensor data rose above the expected range, determining whether elevated levels in the sensor data are observed in gas concentrations, released from the capsules, and in an internal air temperature.

9. The battery health and safety management system of claim 8, wherein the implementing the alert logic comprises, when the elevated levels in the sensor data are not observed in the gas concentrations and in the internal air temperature:
determining that the battery pack is experiencing severe aging; and
limiting battery current of the battery pack.

10. The battery health and safety management system of claim 8, wherein the implementing the alert logic comprises, when the elevated levels in the sensor data are observed in the gas concentrations and in the internal air temperature, limiting battery output of the battery pack.

11. The battery health and safety management system of claim 10, wherein the implementing the alert logic comprises, after limiting the battery output of the battery pack:
determining whether the sensor data continues to increase; and
when the sensor data continues to increase, opening the venting mechanism to allow venting.

12. A method for detecting battery anomalies of a vehicle, comprising:
recording sensor data via one or more sensors of a battery health and safety management system;
wherein the battery health and safety management system comprises:
the vehicle;
an active sensing and venting module (ASVM) coupled to the vehicle, comprising:
a fan;
the one or more sensors; and
a venting mechanism; and
a battery pack comprising:
a plurality of battery cells;
an insulator positioned between the plurality of battery cells; and
one or more capsules positioned within or on the insulator,
wherein:
the one or more capsules are configured to:
house a gas; and
rupture in a thermal event in a battery cell, releasing the gas,
the one or more sensors are configured to detect the gas after a rupture of one or more of the one or more capsules; and
determining, using a computing device comprises a processor and a memory, whether the sensor data is within an expected range.

13. The method of claim 12, further comprising, using the computing device:
generating a vehicle-specific correlation between controller area network (CAN) data and the sensor data; and
updating the expected range.

14. The method of claim 12, further comprising, when the sensor data is not within the expected range, activating an alert status comprising implementing alert logic.

15. The method of claim 14, wherein the implementing the alert logic comprises determining whether the sensor date rose above or dropped below the expected range.

16. The method of claim 15, wherein the implementing the alert logic comprises, when the sensor data dropped below the expected range:
determining that the battery pack comprises a compromised seal; and
generating an alert to one or more passengers of the vehicle to exit the vehicle.

17. The method of claim 15, wherein:
the one or more sensors comprise a CO concentration sensor; a CO₂ concentration sensor;
and an airflow thermometer, and
the implementing the alert logic comprises, when the sensor data rose above the expected range, determining whether elevated levels in the sensor data are observed in gas concentrations, released from the capsules, and in an internal air temperature.

18. The method of claim 17, wherein the implementing the alert logic comprises, when the elevated levels in the sensor data are not observed in the gas concentrations and in the internal air temperature:
determining that the battery pack is experiencing severe aging; and
limiting battery current of the battery pack.

19. The method of claim 17, wherein the implementing the alert logic comprises, when the elevated levels in the sensor data are observed in the gas concentrations and in the internal air temperature, limiting battery output of the battery pack.

20. The method of claim 19, wherein the implementing the alert logic comprises, after limiting the battery output of the battery pack:
determining whether the sensor data continues to increase; and
when the sensor data continues to increase, opening the venting mechanism to allow venting.
